(19) United States
(12) Patent Application Publication
(10) Pub. No.: US 2023/0246043 A1
(43) Pub. Date: Aug. 3, 2023

(54) SEMICONDUCTOR DEVICE AND IMAGING APPARATUS

(71) Applicant: SONY SEMICONDUCTOR SOLUTIONS CORPORATION, KANAGAWA (JP)

(72) Inventor: RYOHEI TAKAYANAGI, KANAGAWA (JP)

(21) Appl. No.: 18/002,587

(22) PCT Filed: May 17, 2021
(86) PCT No.: PCT/JP2021/018582

§ 371 Date: Dec. 20, 2022

(30) Foreign Application Priority Data
Jun. 29, 2020 (JP) 2020-111074

(51) Int. Cl. H01L 27/146; H04N 25/78

(52) U.S. Cl. CPC H01L 27/14614; H01L 27/14616; H04N 25/78

(57) ABSTRACT

A semiconductor device and an imaging apparatus capable of suppressing short-channel effects are provided. The semiconductor device includes a semiconductor substrate and a transistor provided on the semiconductor substrate. The transistor includes a semiconductor region having a main surface and a first side surface intersecting the main surface, a gate insulating film provided on the semiconductor region, a gate electrode provided on the gate insulating film, a channel region covered with the gate insulating film and the gate electrode in the semiconductor region, and first-conductivity-type source and drain regions adjacent to the channel region. In a planar view from the normal direction of the main surface, the semiconductor region includes a first portion extended in a first direction, and a second portion extended from the first portion in a second direction intersecting the first direction. The channel region includes a first channel region present on the main surface, and a second channel region present on the first side surface and extending in the direction of depth of the semiconductor region.

### TECHNICAL FIELD

The present disclosure relates to a semiconductor device and an imaging apparatus.

### BACKGROUND ART

Of imaging devices, a CMOS image sensor (CIS) is installed with pixel transistors (amplification transistors, select transistors, and reset transistors) for amplifying and reading pixel signals. Typically, regions filled with an insulator called shallow trench isolation (STI) are present at both ends of the channel region of a pixel transistor. The STI defines the width of the channel region. To improve the area efficiency of pixel transistors with the miniaturization of pixels, a structure has been proposed in which the channel shape in a planar view of a transfer transistor that transfers a pixel signal from a photodiode to an amplification transistor is bent in an L shape (see, for example, FIG. 2 of Patent Document 1).

### CITATION LIST

### Patent Document

Patent Document 1: US 2016/0,064,446 A

### SUMMARY OF THE INVENTION

### Problems to be Solved by the Invention

In a case where the shape of a channel in a planar view is an L shape, the length of a current path in the channel on the interior-angle side of the L is different from that on the exterior-angle side. The length of the current path on the interior-angle side of the L is shorter than that on the exterior-angle side of the L, and thus transistor characteristics may be degraded (for example, leakage current in an off state may be increased) due to short-channel effects.

The present disclosure has been made in view of such circumstances, and an object thereof is to provide a semiconductor device and an imaging apparatus capable of suppressing short-channel effects.

### Solutions to Problems

A semiconductor device according to an aspect of the present disclosure includes a semiconductor substrate and a transistor provided on the semiconductor substrate. The transistor includes a semiconductor region having a main surface and a first side surface intersecting the main surface, a gate insulating film provided on the semiconductor region, a gate electrode provided on the gate insulating film, a channel region covered with the gate insulating film and the gate electrode in the semiconductor region, and first-conductivity-type source and drain regions adjacent to the channel region. In a planar view from the normal direction of the main surface, the semiconductor region includes a first portion extended in a first direction, and a second portion extended from the first portion in a second direction intersecting the first direction. The channel region includes a first channel region present on the main surface, and a second channel region present on the first side surface and extending in the direction of depth of the semiconductor region.

With this configuration, the shape of the semiconductor region in the planar view is not linear but is, for example, an L shape. Consequently, the transistor can improve area efficiency, facilitating miniaturization. Furthermore, the transistor can apply the gate voltage from at least two directions of the main surface and the first side surface of the semiconductor region to pass drain current. Consequently, the transistor can improve gate controllability and can prevent subthreshold characteristic degradation, which is a short-channel effect.

An imaging apparatus according to an aspect of the present invention includes a pixel that performs photoelectric conversion, and an amplification transistor that amplifies a voltage signal corresponding to the level of charge output from the pixel. The amplification transistor includes a semiconductor region having a main surface and a first side surface intersecting the main surface, a gate insulating film provided on the semiconductor region, a gate electrode provided on the gate insulating film, a channel region covered with the gate insulating film and the gate electrode in the semiconductor region, and first-conductivity-type source and drain regions adjacent to the channel region. In a planar view from the normal direction of the main surface, the semiconductor region includes a first portion extended in a first direction, and a second portion extended from the first portion in a second direction intersecting the first direction. The channel region includes a first channel region present on the main surface, and a second channel region present on the first side surface and extending in the direction of depth of the semiconductor region.

With this configuration, the imaging apparatus can suppress short-channel effects in the amplification transistor.

An imaging apparatus according to another aspect of the present invention includes a pixel that performs photoelectric conversion, and a readout circuit that reads out charge generated by photoelectric conversion in the pixel. The pixel includes a floating diffusion that temporarily stores charge generated by photoelectric conversion. The readout circuit includes an amplification transistor that amplifies a voltage signal according to the level of charge output from the floating diffusion, a select transistor that controls timing to output the signal amplified by the amplification transistor from the readout circuit, and a reset transistor that resets the potential of the floating diffusion to a preset potential. At least one transistor of the amplification transistor, the select transistor, or the reset transistor includes a semiconductor region having a main surface and a first side surface intersecting the main surface, a gate insulating film provided on the semiconductor region, a gate electrode provided on the gate insulating film, a channel region covered with the gate insulating film and the gate electrode in the semiconductor region, and first-conductivity-type source and drain regions adjacent to the channel region. In a planar view from the normal direction of the main surface, the semiconductor region includes a first portion extended in a first direction, and a second portion extended from the first portion in a second direction intersecting the first direction. The channel region includes a first channel region present on the main surface, and a second channel region present on the first side surface and extending in the direction of depth of the semiconductor region.

With this configuration, the imaging apparatus can suppress short-channel effects for at least one transistor of the amplification transistor, the select transistor, or the reset transistor.

### BRIEF DESCRIPTION OF DRAWINGS

FIG. 1 is a block diagram illustrating a configuration example of an imaging apparatus according to a first embodiment of the present disclosure.

FIG. 2 is a plan view illustrating a configuration example of a MOS transistor according to the first embodiment of the present disclosure.

FIG. 3 is a plan view illustrating the configuration example of the MOS transistor according to the first embodiment of the present disclosure.

FIG. 4 is a cross-sectional view illustrating the configuration example of the MOS transistor according to the first embodiment of the present disclosure.

FIG. 5 is a plan view illustrating an L-shaped semiconductor region in which a channel region is formed, and a drain region and a source region in the MOS transistor according to the first embodiment of the present disclosure.

FIG. 6 is cross-sectional views illustrating a method of manufacturing the MOS transistor according to the first embodiment of the present disclosure in order of processes.

FIG. 7 is a cross-sectional view illustrating a configuration example of a MOS transistor according to a second embodiment of the present disclosure.

FIG. 8 is a cross-sectional view illustrating a configuration of a MOS transistor according to a modification of the second embodiment of the present disclosure.

FIG. 9 is a cross-sectional view illustrating a configuration example of a MOS transistor according to a third embodiment of the present disclosure.

FIG. 10 is a cross-sectional view illustrating a configuration example of a MOS transistor according to a fourth embodiment of the present disclosure.

FIG. 11 is a plan view illustrating a configuration example of a MOS transistor according to a fifth embodiment of the present disclosure.

FIG. 12 is a cross-sectional view illustrating the configuration example of the MOS transistor according to the fifth embodiment of the present disclosure.

FIG. 13 is a plan view illustrating a configuration of a MOS transistor according to a modification of the fifth embodiment of the present disclosure.

FIG. 14 is a plan view illustrating a configuration example of a MOS transistor according to a sixth embodiment of the present disclosure.

FIG. 15 is a cross-sectional view illustrating a configuration example of a MOS transistor according to a seventh embodiment of the present disclosure.

FIG. 16 is cross-sectional views illustrating a method of manufacturing the MOS transistor according to the seventh embodiment of the present disclosure in order of processes.

FIG. 17 is cross-sectional views illustrating the method of manufacturing the MOS transistor according to the seventh embodiment of the present disclosure in order of processes.

### MODE FOR CARRYING OUT THE INVENTION

Hereinafter, embodiments of the present disclosure will be described with reference to the drawings. In the description of the drawings referred to in the following description, identical or similar reference numerals are assigned to identical or similar parts. However, it should be noted that the drawings are schematic, and the relationships between thicknesses and plane dimensions, the ratios between the thicknesses of individual layers, etc. are different from actual ones. Thus, specific thicknesses and dimensions should be determined in consideration of the following description. Furthermore, it is needless to say that the drawings include portions where each other's dimensional relationships and ratios are different between them.

The definitions of directions such as up and down in the following description are merely definitions for convenience of explanation and do not limit the technical idea of the present disclosure. For example, it is a matter of course that if an object is rotated 90° and observed, up and down are converted into left and right when read, and if rotated 180° and observed, up and down are inverted when read.

In the following description, directions are sometimes explained using words of an X-axis direction, a Y-axis direction, and a Z-axis direction. For example, the X-axis direction and the Y-axis direction are directions parallel to a main surface 52a of a semiconductor region 52. No the X-axis direction and the Y-axis direction are also referred to as a horizontal direction. The Z-axis direction is the normal direction of the main surface 52a of the semiconductor region 52. The X-axis direction, the Y-axis direction, and the Z-axis direction are orthogonal to each other.

### First Embodiment

### Configuration Example of Imaging Apparatus

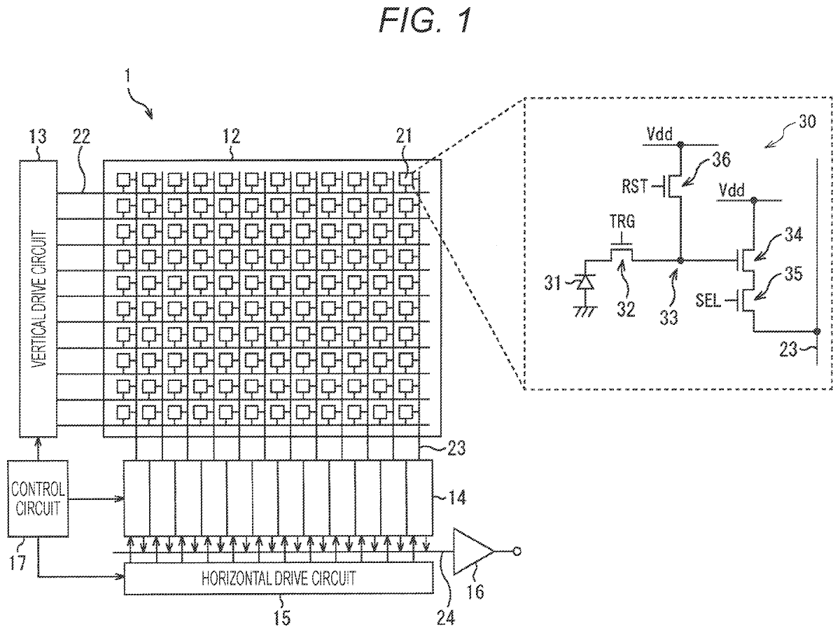

FIG. 1 is a block diagram illustrating a configuration example of an imaging apparatus 1 according to a first embodiment of the present disclosure. As illustrated in FIG. 1, the imaging apparatus 1 includes a plurality of pixels 12, a vertical drive circuit 13, column signal processing circuits 14, a horizontal drive circuit 15, an output circuit 16, and a control circuit 17.

Each pixel 12 is a light-receiving region that receives light collected by an optical system (not illustrated). The plurality of pixels 21 is arranged in a matrix. The plurality of pixels 21 is connected to the vertical drive circuit 13 row by row via horizontal signal lines 22, and is connected to the column signal processing circuits 14 column by column via vertical signal lines 23. Each of the plurality of pixels 21 outputs a pixel signal at a level corresponding to the amount of light received by it individually. A subject image is constructed from the pixel signals.

The vertical drive circuit 13 provides a drive signal to the plurality of pixels 21 in each row of the pixels 21 in sequence via the horizontal signal lines 22 for driving the individual pixels 21 (transfer, selection, reset, etc). The column signal processing circuits 14 perform correlated double sampling (CDS) processing on pixel signals output from the plurality of pixels 21 via the vertical signal lines 23, thereby performing A/D conversion on the pixel signals and removing reset noise.

The horizontal drive circuit 15 provides a drive signal to each column signal processing circuit 14 in sequence to cause the column signal processing circuit 14 to output a pixel signal of the corresponding column of the plurality of pixels 21 to the data output signal line 24. The output circuit 16 amplifies the pixel signal provided from each column signal processing circuit 14 via the data output signal line 24 at a timing according to the drive signal of the horizontal drive circuit 15, and outputs it to a signal processing circuit in the subsequent stage. The control circuit 17 controls the drive of each block inside the imaging apparatus 1. For example, the control circuit 17 generates clock signals according to the drive cycles of the individual blocks and provides them to the respective blocks.

Each pixel 21 includes a photodiode 31, a transfer transistor 32, a floating diffusion 33, an amplification transistor 34, a select transistor 35, and a reset transistor 36. The transfer transistor 32, the floating diffusion 33, the amplification transistor 34, the select transistor 35, and the reset transistor 36 constitute a readout circuit 30 that reads charge (a pixel signal) generated by photoelectric conversion in the photodiode 31.

The photodiode 31 is a photoelectric conversion unit that converts incident light into charge by photoelectric conversion and accumulates it, and has an anode terminal grounded and a cathode terminal connected to the transfer transistor 32. The transfer transistor 32 is driven in accordance with a transfer signal TRG provided from the vertical drive circuit 13. When the transfer transistor 32 is turned on, the charge accumulated in the photodiode 31 is transferred to the floating diffusion 33. The floating diffusion 33 is a floating diffusion region having a predetermined storage capacitance and connected to the gate electrode of the amplification transistor 34, and temporarily stores the charge transferred from the photodiode 31.

The amplification transistor 34 amplifies the pixel signal according to the level of the charge accumulated in the floating diffusion 33 (that is, the potential of the floating diffusion 33), and outputs the amplified pixel signal to the vertical signal line 23 via the select transistor 35. That is, with the configuration in which the floating diffusion 33 is connected to the gate electrode of the amplification transistor 34, the floating diffusion 33 and the amplification transistor 34 function as a conversion unit that amplifies charge generated in the photodiode 31 and converts the charge into a pixel signal at a corresponding level.

The select transistor 35 controls timing to output the pixel signal amplified by the amplification transistor 34 from the readout circuit 30. For example, the select transistor 35 is driven in accordance with a selection signal SEL provided from the vertical drive circuit 13. When the select transistor 35 is turned on, the pixel signal output from the amplification transistor 34 can be output to the vertical signal line 23. The reset transistor 36 resets the potential of the floating diffusion 33 to a preset potential (e.g., power supply potential). For example, when the reset transistor 36 is driven in accordance with a reset signal RST provided from the vertical drive circuit 13 and is turned on, the charge accumulated in the floating diffusion 33 is discharged to a drain power supply Vdd to reset the floating diffusion 33.

The readout circuit 30 may be formed on one semiconductor substrate or may be formed on a laminated substrate in which two or more semiconductor substrates are stacked in the thickness direction. For example, in a case where a laminated substrate includes a first semiconductor substrate and a second semiconductor substrate placed on top of the first semiconductor substrate, part of the readout circuit 30 may be formed on the first semiconductor substrate, and the other part of the readout circuit 30 may be formed on the second semiconductor substrate. As an example, the photodiode 31, the transfer transistor 32, and the floating diffusion 33 may be formed on the first semiconductor substrate, and the amplification transistor 34, the select transistor 35, and the reset transistor 36 may be formed on the second semiconductor substrate.

The amplification transistor 34 illustrated in FIG. 1 is constituted by, for example, any one of metal-oxide-semiconductor (MOS) transistors 50 and 50A to 50H described below. Each of the MOS transistors 50 and 50A to 50H is an example of a “transistor” of the present disclosure.

### Transistor Configuration Example

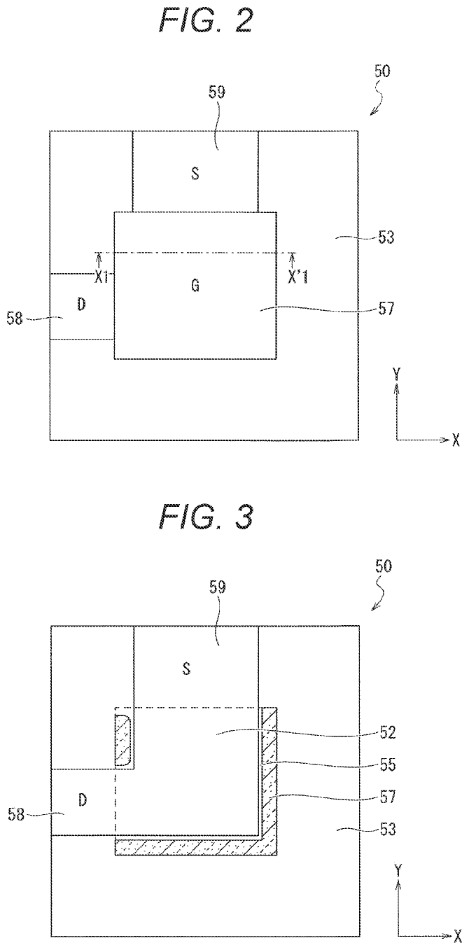

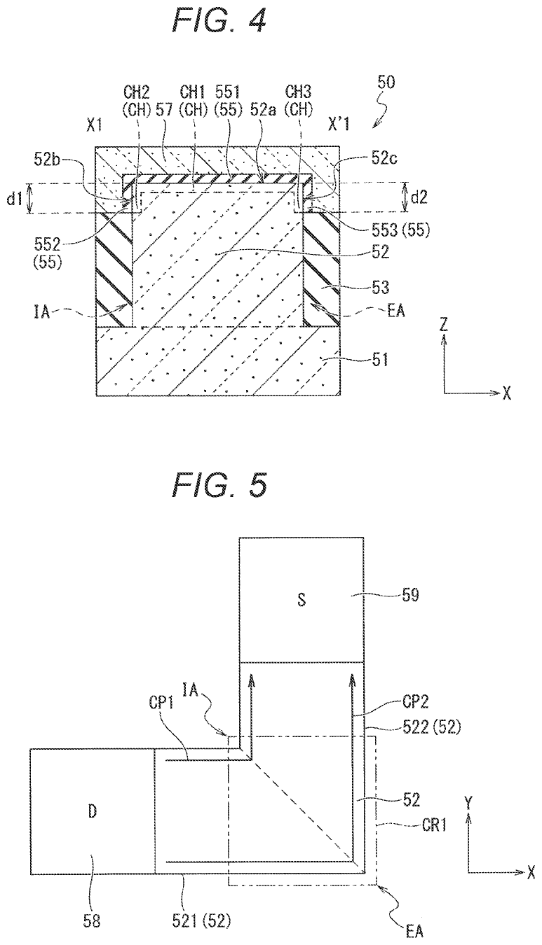

FIGS. 2 and 3 are plan views illustrating a configuration example of the MOS transistor 50 according to the first embodiment of the present disclosure. Note that FIG. 3 illustrates a gate electrode 57 illustrated in FIG. 2 cut along an X-Y plane parallel to the X-axis direction and the Y-axis direction (that is, the horizontal direction). FIG. 4 is a cross-sectional view illustrating the configuration example of the MOS transistor 50 according to the first embodiment of the present disclosure. FIG. 4 illustrates a cross section of FIG. 1 taken along line X1-X′1. FIG. 5 is a plan view illustrating an L-shaped semiconductor region 52 in which a channel region CH is formed, and a drain region 58 and a source region 59 in the MOS transistor 50 according to the first embodiment of the present disclosure.

As illustrated in FIGS. 2 to 5, the MOS transistor 50 is provided on one-surface (e.g., the front) side of the semiconductor substrate 51. The semiconductor substrate 51 includes, for example, single-crystal silicon. The MOS transistor 50 is electrically isolated from other elements by an element isolation film 53 having a shallow trench isolation (STI) structure provided on the front side of the semiconductor substrate 51. The element isolation film 53 is an insulating film and is constituted by, for example, a silicon oxide film (SiO₂ film). The thickness of the element isolation film 53 (that is, the depth of the STI) is, for example, 200 nm or more and 300 nm or less.

The MOS transistor 50 is a first-conductivity-type (e.g., N-type) MOS transistor. The MOS transistor 50 includes the semiconductor region 52 of a second conductivity type (e.g., the P-type) different from the first conductivity type, in which the channel region CH is formed, a gate insulating film 55, the gate electrode 57, the N-type drain region 58 provided in the semiconductor substrate 51, and the N-type source region 59 provided in the semiconductor substrate 51. The channel region CH in the semiconductor region 52 is covered with the gate insulating film 55 and the gate electrode 57. The N-type drain region 58 and the N-type source region 59 are adjacent to the channel region CH.

The semiconductor region 52 is a part of the semiconductor substrate 51 and includes single-crystal silicon. Alternatively, the semiconductor region 52 may be a single-crystal silicon layer formed on the semiconductor substrate 51 by an epitaxial growth method. The semiconductor region 52 is a portion formed in an island shape by etching a part of the front side of the semiconductor substrate 51.

As illustrated in FIG. 4, the cross section of the semiconductor region 52 taken along a plane parallel to the Z-axis direction has a rectangular shape. In addition, as illustrated in FIG. 5, the semiconductor region 52 has an L shape in a planar view from the normal direction of the main surface 52a of the semiconductor region 52 (e.g., the direction perpendicular to the sheet surface of FIG. 5). That is, in the planar view from the normal direction of the main surface 52a of the semiconductor region 52, the semiconductor region 52 includes a first portion 521 extended in a first direction and a second portion 522 extended in a second direction from one end of the first portion 521. The second direction is a direction intersecting the first direction. For example, the first direction is the X-axis direction, and the second direction is the Y-axis direction orthogonal to the X-axis direction.

As illustrated in FIG. 4, the semiconductor region 52 includes the main surface 52a, a first side surface 52b intersecting the main surface 52a, and a second side surface 52c located opposite the first side surface 52b across the main surface 52a. As illustrated in FIG. 5, the first side surface 52b is located on the interior angle IA side of a first corner portion CR1 formed by the first portion 521 and the second portion 522. The second side surface 52c is located on the exterior angle EA side of the first corner portion CR1.

The channel region CH includes a first channel region CH1 present on the main surface 52a, a second channel region CH2 present on the first side surface 52b, and a second channel region CH2 present on the second side surface 52c. The second channel region CH2 extends in the direction of depth of the semiconductor region 52 (in FIG. 4, the direction opposite to the arrow of the Z axis) from the side of one end of the first channel region CH1 in the channel width direction (e.g., the interior-angle side of the first corner portion CR1). The third channel region CH3 extends in the direction of depth of the semiconductor region 52 from the side of the other end of the first channel region CH1 in the channel width direction (e.g., the exterior-angle side of the first corner portion CR1)

Thus, the gate electrode 57 can apply the gate voltage to the main surface 52a, the first side surface 52b, and the second side surface 52c of the semiconductor region 52 simultaneously. That is, the gate electrode 57 can apply the gate voltage to the semiconductor region 52 from total three directions, from above and from both left and right, simultaneously. This improves gate controllability in the MOS transistor 50, allowing the suppression of short-channel effects.

The gate insulating film 55 is provided to continuously cover the main surface 52a, the first side surface 52b, and the second side surface 52c of the semiconductor region 52. The gate insulating film 55 includes, for example, SiO₂ or its nitride, silicon oxynitride (SiON). Alternatively, the gate insulating film 55 may include hafnium oxide (HfO₂) or its nitride, hafnium oxynitride (HfON).

The gate insulating film 55 includes a first film portion 551 provided on the main surface 52a of the semiconductor region 52, a second film portion 552 provided on the first side surface 52b of the semiconductor region 52, and a third film portion 553 provided on the second side surface 52c of the semiconductor region 52.

In the MOS transistor 50, the second film portion 552 and the third film portion 553 of the gate insulating film 55 have the same dimension in length in the depth direction (e.g., the Z-axis direction) from the main surface 52a of the semiconductor region 52. This length may be referred to as a dug depth. d1=d2, where d1 is the length of the second film portion 552 in the Z-axis direction from the main surface 52a (dug depth), and d2 is the length of the third film portion 553 in the Z-axis direction from the main surface 52a (dug depth). For example, each of the lengths d1 and d2 is preferably 0.01 μm or more and 0.1 μm or less.

The gate electrode 57 is provided to continuously cover the main surface 52a, the first side surface 52b, and the second side surface 52c of the semiconductor region 52 with the gate insulating film 55 therebetween. The gate electrode 57 is constituted by, for example, a polysilicon (Poly-Si) film. Alternatively, the gate electrode 57 may include metal or metal nitride.

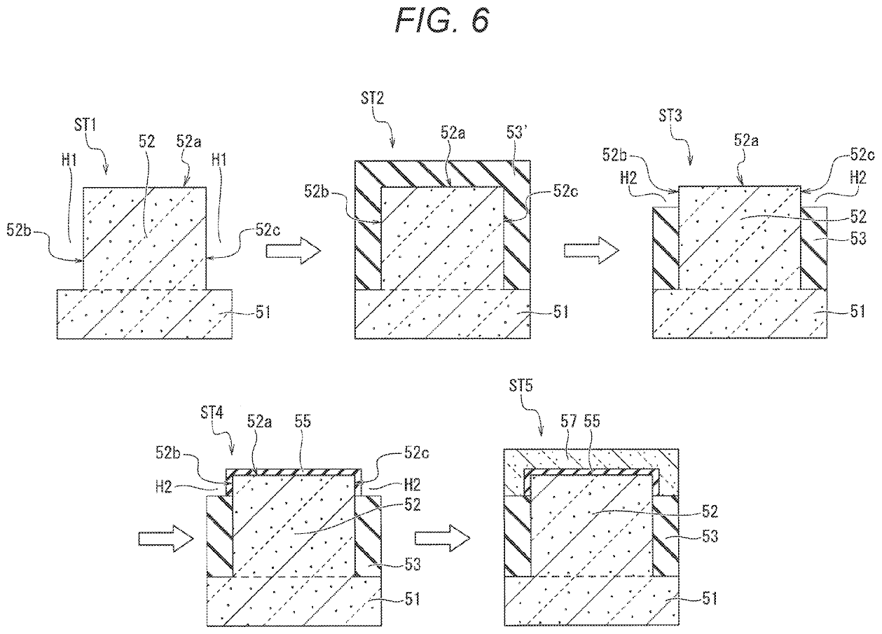

The MOS transistor 50 may be called a dug-gate-structure MOS transistor from its shape in which trenches H2 (see FIG. 6 described later) are formed on both sides of the semiconductor region 52, and parts of the gate electrode 57 are disposed in the trenches.

### Manufacturing Method

Next, an example of a method of manufacturing the MOS transistor 50 according to the first embodiment of the present disclosure will be described. The MOS transistor 50 is manufactured using various apparatuses including film formation equipment (including a chemical vapor deposition (CVD) apparatus, a thermal oxidation furnace, a sputtering apparatus, and a resist coating apparatus), an exposure apparatus, an ion implantation apparatus, an annealing apparatus, an etching apparatus, and a chemical mechanical polishing (CMP) apparatus. Hereinafter, these apparatuses are collectively referred to as manufacturing equipment.

FIG. 6 is cross-sectional views illustrating the method of manufacturing the MOS transistor 50 according to the first embodiment of the present disclosure in order of processes. The manufacturing equipment partially etches the front side of the semiconductor substrate 51 to form trenches H1 (step ST1). The trenches H1 may be referred to as dug regions. The semiconductor region 52 having the main surface 52a, the first side surface 52b, and the second side surface 52c is defined by forming the trenches H1 (dug regions). For example, in a planar view from the normal direction of the main surface 52a of the semiconductor region 52, the trenches H1 are formed to enclose the semiconductor region 52.

Next, the manufacturing equipment deposits an insulating film 53′ on the semiconductor substrate 51 using a CVD method (step ST2). The insulating film 53′ is, for example, an SiO₂ film. Next, the manufacturing equipment etches the insulating film 53′ to form trenches H2 with the insulating film 53′ as the bottom surfaces (step ST3). This process may be referred to as recessing. The recessing may be performed by dry etching, wet etching, or a combination thereof. By the recessing, the main surface 52a, an upper portion of the first side surface 52b, and an upper portion of the second side surface 52c of the semiconductor region 52 are each exposed from the insulating film 53′, and the element isolation film 53 includes the insulating film 53′.

Next, the manufacturing equipment thermally oxidizes the semiconductor region 52. As a result, the gate insulating film 55 is continuously formed on the main surface 52a, the upper portion of the first side surface 52b, and the upper portion of the second side surface 52c of the semiconductor region 52 exposed from the element isolation film 53 (step ST4).

Next, the manufacturing equipment forms an electrode material (e.g., a polysilicon film) above the semiconductor substrate 51, using a CVD method, and fills the trenches H2. Next, the manufacturing equipment patterns the electrode material using photolithography and etching techniques. Thus, the manufacturing equipment forms the gate electrode 57 from the electrode material (step ST5).

Then, the manufacturing equipment ion-implants an n-type impurity into the semiconductor substrate 51, using the gate electrode 57 as a mask. For example, the manufacturing equipment ion-implants the N-type impurity into a region exposed from the gate electrode 57 in the semiconductor region 52. Next, the manufacturing equipment applies annealing treatment to the semiconductor substrate 51 to activate the ion-implanted N-type impurity. Consequently, the drain region 58 and the source region 59 of the N-type are formed. Through the above processes, the MOS transistor 50 is completed.

### Effects of First Embodiment

As described above, the semiconductor device according to the first embodiment of the present disclosure includes the semiconductor substrate 51 and the MOS transistor 50 provided on the semiconductor substrate 51. The MOS transistor 50 includes the semiconductor region 52, the gate insulating film 55 provided on the semiconductor region 52, the gate electrode 57 provided on the gate insulating film 55, and the channel region CH in the semiconductor region 52 covered with the gate insulating film 55 and the gate electrode 57. The semiconductor region 52 has the main surface 52a and the first side surface 52b intersecting (e.g., at right angles) the main surface 52a. In a planar view from the normal direction of the main surface 52a, the semiconductor region 52 includes the first portion 521 extended in the first direction (e.g., the X-axis direction) and the second portion 522 extended in the second direction (e.g., the Y-axis direction) from the first portion 521. The channel region CH includes the first channel region CH1 present on the main surface 52a, and the second channel region CH2 present on the first side surface 52b and extending in the direction of depth of the semiconductor region 52.

Thus, the shape of the semiconductor region 52 in the planar view is not linear but is, for example, an L shape. Consequently, the MOS transistor 50 can improve area efficiency, facilitating miniaturization. Furthermore, the MOS transistor 50 can apply the gate voltage from at least two directions of the main surface 52a and the first side surface 52b of the semiconductor region 52 to pass drain current. Consequently, the MOS transistor 50 can improve gate controllability and can prevent subthreshold characteristic degradation, which is a short-channel effect.

In addition, the semiconductor region 52 further includes the second side surface 52c located opposite the first side surface 52b across the main surface 52a. The channel region CH further includes the third channel region CH3 present on the second side surface 52c and extending in the direction of depth of the semiconductor region 52 (e.g., the Z-axis direction). The first side surface 52b is located on the interior-angle side of the first corner portion CR1 formed by the first portion 521 and the second portion 522. The second side surface 52c is located on the exterior-angle side of the first corner portion CR1.

With this configuration, the MOS transistor 50 can apply the gate voltage from three directions of the main surface 52a, the first side surface 52b, and the second side surface 52c of the semiconductor region 52 to pass drain current. Consequently, the MOS transistor 50 can further improve gate controllability and can further prevent subthreshold characteristic degradation.

Furthermore, the imaging apparatus 1 according to the first embodiment of the present disclosure includes the pixels 12 that perform photoelectric conversion, and the amplification transistor 34 that amplifies a voltage signal corresponding to the level of charge output from each pixel 12. For example, the MOS transistor 50 is used as the amplification transistor 34. Consequently, the imaging apparatus 1 can suppress short-channel effects in the amplification transistor 34.

### Second Embodiment

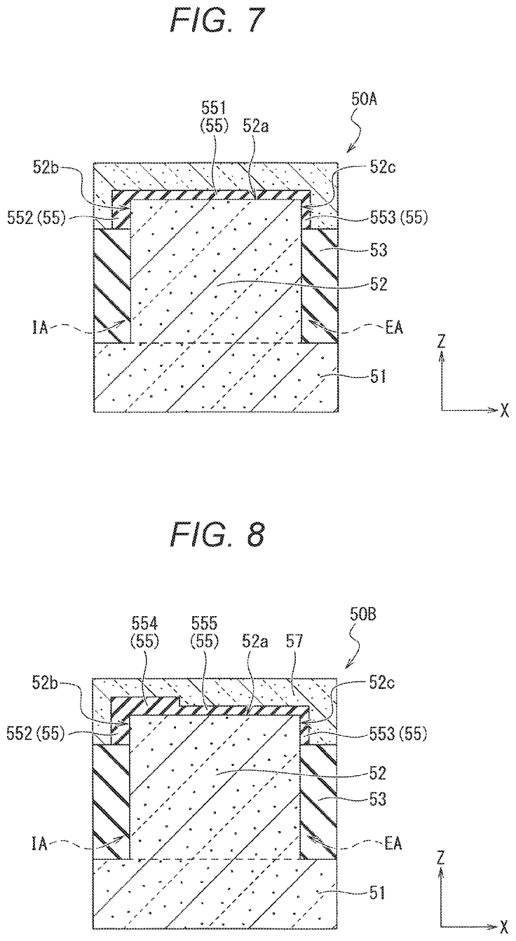

FIG. 7 is a cross-sectional view illustrating a configuration example of a MOS transistor 50A according to a second embodiment of the present disclosure. As illustrated in FIG. 7, in the MOS transistor 50A, a gate insulating film 55 includes a first film portion 551 provided on a main surface 52a of a semiconductor region 52, a second film portion 552 provided on a first side surface 52b of the semiconductor region 52, and a third film portion 553 provided on a second side surface 52c of the semiconductor region 52. The second film portion 552 is greater in film thickness than the first film portion 551. Further, the second film portion 552 is greater in film thickness than the third film portion 553. For example, the second film portion 552 is thicker than the first film portion 551 by 0.5 nm or more. Further, the second film portion 552 is thicker than the third film portion 553 by 0.5 nm or more. The first film portion 551 and the third film portion 553 may have the same thickness.

Even with this configuration, the MOS transistor 50A can apply the gate voltage from three directions of the main surface 52a, the first side surface 52b, and the second side surface 52c of the semiconductor region 52 to pass drain current. Consequently, like the MOS transistor 50 of the first embodiment, the MOS transistor 50A can improve gate controllability and can prevent subthreshold characteristic degradation.

Furthermore, the second film portion 552 is thicker than each of the first film portion 551 and the third film portion 553, and is preferably thicker than each of the first film portion 551 and the third film portion 553 by 0.5 nm or more. As illustrated in FIG. 5, for the current path between the drain region 58 and the source region 59, the current path CP1 on the interior angle IA side of the first corner portion CR1 is shorter than the current path CP2 on the exterior angle EA side (that is, the second side surface 52c side). However, by thickening the second film portion 552 of the gate insulating film 55 as described above, a threshold voltage Vth on the interior angle IA side can be made higher than a threshold voltage Vth on the exterior angle EA side. Consequently, the MOS transistor 50A can prevent the concentration of drain current on the interior angle IA side where the current path is short, and the increase of leakage current on the interior angle IA side, and can further suppress short-channel effects.

### Modification

FIG. 8 is a cross-sectional view illustrating a configuration of a MOS transistor 50B according to a modification of the second embodiment of the present disclosure. As illustrated in FIG. 8, in the MOS transistor 50B, the gate insulating film 55 includes a fourth film portion 554 and a fifth film portion 555 provided on the main surface 52a of the semiconductor region 52. The fourth film portion 554 is located on the side close to the first side surface 52b, and the fifth film portion 555 is located on the side close to the second side surface 52c. The fourth film portion 554 has a greater film thickness than the fifth film portion 555.

Furthermore, the second film portion 552 of the gate insulating film 55 provided on the first side surface 52b of the semiconductor region 52 may have the same film thickness as the fourth film portion 554 provided on the main surface 52a, or may have a greater film thickness than the fourth film portion 554. The third film portion 553 of the gate insulating film 55 provided on the second side surface 52c of the semiconductor region 52 may have the same film thickness as the fifth film portion 555 provided on the main surface 52a, or may have a smaller film thickness than the fifth film portion 555. The magnitude relationships between the individual film thicknesses of the second film portion 552, the third film portion 553, the fourth film portion 554, and the fifth film portion 555 are the second film portion 552≥the fourth film portion 554>the fifth film portion 555≥the third film portion 553.

Even with this configuration, the MOS transistor 50B can make the threshold voltage Vth on the interior angle IA side higher than the threshold voltage Vth on the exterior angle EA side. Consequently, the MOS transistor 50B can prevent the concentration of drain current on the interior angle IA side where the current path is short (that is, on the first side surface 52b side) and the increase of leakage current on the interior angle IA side, and can further suppress short-channel effects.

### Third Embodiment

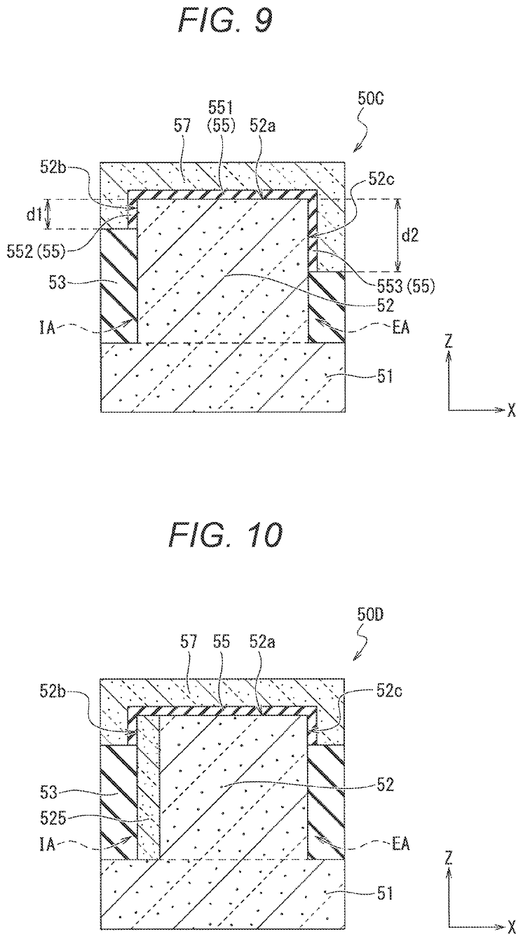

FIG. 9 is a cross-sectional view illustrating a configuration example of a MOS transistor 50C according to a third embodiment of the present disclosure. As illustrated in FIG. 9, in the MOS transistor 50C, a third film portion 553 of a gate insulating film 55 is longer in length in the depth direction (e.g., the Z-axis direction) from a main surface 52a of a semiconductor region 52 than a second film portion 552 of the gate insulating film 55. d1<d2, where d1 is the length of the second film portion 552 in the Z-axis direction from the main surface 52a (dug depth), and d2 is the length of the third film portion 553 in the Z-axis direction from the main surface 52a (dug depth). For example, d2 is preferably longer than d1 by 10 nm or more.

With this configuration, the current path CP2 on the exterior angle EA side (that is, the second side surface 52c side) illustrated in FIG. 5 is wider in the direction of depth of the semiconductor region 52 (e.g., the Z-axis direction) than the current path CP1 on the interior angle IA side (that is, the first side surface 52b side). For example, the current path CP2 on the exterior angle EA side is wider than the current path CP1 on the interior angle IA side by 10 nm or more in the Z-axis direction. Consequently, the MOS transistor 50C can prevent the concentration of drain current on the interior angle IA side where the current path is short and the increase of leakage current on the interior angle IA side, and can further suppress short-channel effects.

### Fourth Embodiment

FIG. 10 is a cross-sectional view illustrating a configuration example of a MOS transistor 50D according to a fourth embodiment of the present disclosure. As illustrated in FIG. 10, the MOS transistor 50D includes a P-type first impurity diffusion layer 525 (an example of an “impurity diffusion layer” of the present disclosure) provided on the first side surface 52b side in the semiconductor region 52. The first impurity diffusion layer 525 has a higher P-type impurity concentration than a region located on the second side surface 52c side in the semiconductor region 52. For example, the P-type impurity concentration (acceptor concentration) of the first impurity diffusion layer 525 is preferably 1×10¹⁷ cm⁻³ or more. Furthermore, the P-type impurity concentration of the first impurity diffusion layer 525 is preferably a value twice or more higher than the P-type impurity concentration of the region located on the second side surface 52c side in the semiconductor region 52.

With this configuration, the MOS transistor 50D can make a threshold voltage Vth on the interior angle IA side (that is, the first side surface 52b side) illustrated in FIG. 5 higher than a threshold voltage Vth on the exterior angle EA side (that is, the second side surface 52c side). Consequently, the MOS transistor 50D can prevent the concentration of drain current on the interior angle IA side where the current path is short and the increase of leakage current on the interior angle IA side, and can further suppress short-channel effects.

### Fifth Embodiment

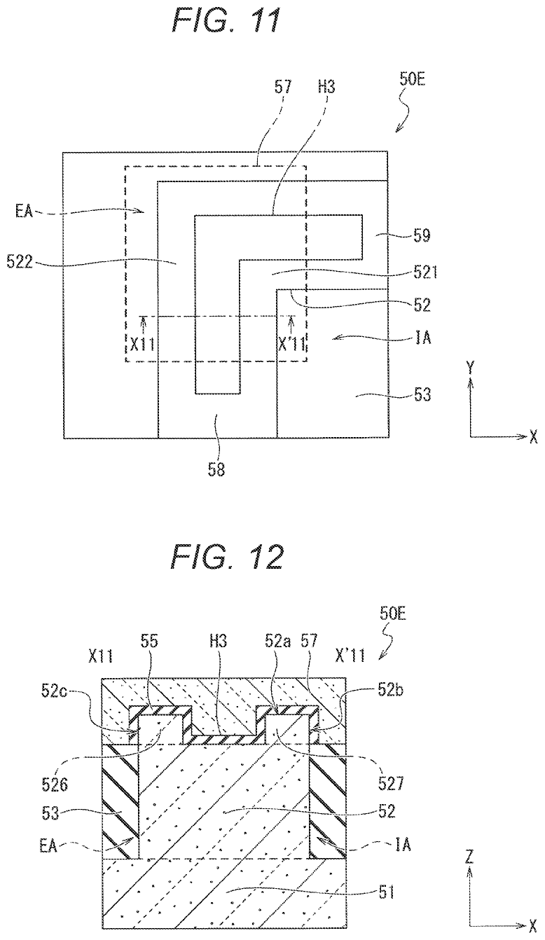

FIG. 11 is a plan view illustrating a configuration example of a MOS transistor 50E according to a fifth embodiment of the present disclosure. FIG. 12 is a cross-sectional view illustrating the configuration example of the MOS transistor 50E according to the fifth embodiment of the present disclosure. In FIG. 11, to illustrate a main surface 52a of a semiconductor region 52, a gate insulating film 55 is not illustrated, and a gate electrode 57 is simply illustrated by broken lines. Furthermore, FIG. 12 corresponds to a cross section of FIG. 11 taken along line X11-X′11.

As illustrated in FIGS. 11 and 12, the MOS transistor 50E includes one trench H3 (an example of a “trench” of the present disclosure) provided on the main surface 52a of the semiconductor region 52 and extended in channel length directions (that is, directions in which drain current flows). The trench H3 may be referred to as a recess. The bottom surface and the side surfaces of the trench H3 are covered with the gate insulating film 55 and the gate electrode 57. The trench H3 is filled with the gate electrode 57 with the gate insulating film 55 therebetween.

With this configuration, in the semiconductor region 52, the gate voltage is applied to a portion 526 located between a first side surface 52b and the trench H3 from total three directions, from above and from left and right, simultaneously. Likewise, in the semiconductor region 52, the gate voltage is applied to a portion 527 located between a second side surface 52c and the trench H3 from total three directions, from above and from left and right, simultaneously. Consequently, consequently, the MOS transistor 50E can further improve gate controllability and can further prevent subthreshold characteristic degradation.

### Modification

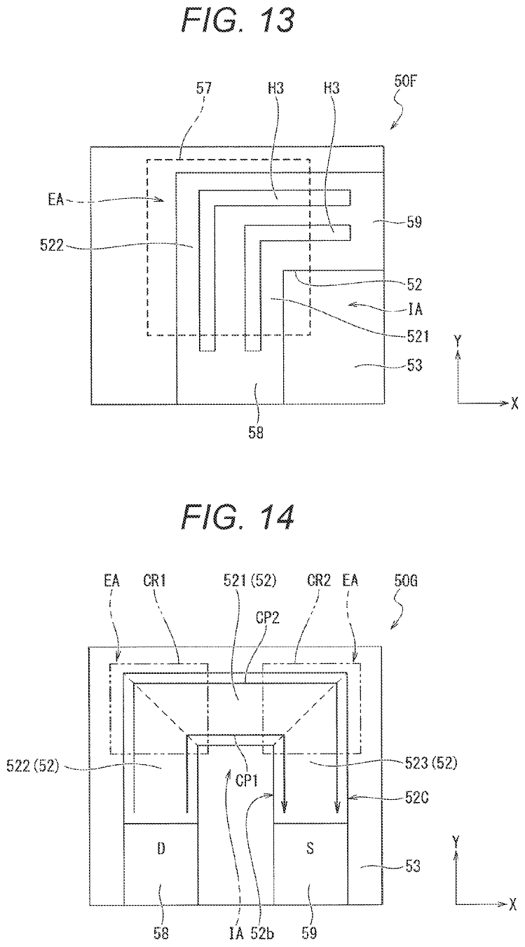

FIG. 13 is a plan view illustrating a configuration of a MOS transistor 50F according to a modification of the fifth embodiment of the present disclosure. As illustrated in FIG. 13, the MOS transistor 50F includes a plurality of (e.g., two) trenches H3 provided on the main surface 52a of the semiconductor region 52 and extended in the channel length directions. With this configuration, in the semiconductor region 52, the number of portions to which the gate voltage is applied from total three directions, from above and from left and right, simultaneously, increases, so that the MOS transistor 50F can further improve gate controllability.

### Sixth Embodiment

FIG. 14 is a plan view illustrating a configuration example of a MOS transistor 50G according to a sixth embodiment of the present disclosure. In FIG. 14, to illustrate the shape of a semiconductor region 52 in a planar view, a gate insulating film 55 is not illustrated, and a gate electrode 57 is simply illustrated by broken lines.

As illustrated in FIG. 14, in the MOS transistor 50G, the semiconductor region 52 has a U shape in a planar view from the normal direction of its main surface 52a (e.g., the Z-axis direction). That is, in the planar view from the normal direction of the main surface 52a of the semiconductor region 52 (e.g., a direction perpendicular to the sheet surface of FIG. 14), the semiconductor region 52 includes a first portion 521 extended in a first direction, a second portion 522 extended in a second direction from one end of the first portion 521, and a third portion 523 extended in the second direction from the other end of the first portion 521 and facing the second portion 522 in the first direction. For example, the first direction is the X-axis direction, and the second direction is the Y-axis direction orthogonal to the X-axis direction.

As illustrated in FIG. 14, a first side surface 52b is located on the inner side of the U shape. The inner side of the U shape is the interior-angle side of a first corner portion CR1 formed by the first portion 521 and the second portion 522, and is also the interior-angle side of a second corner portion CR2 formed by the first portion 521 and the third portion 523. A second side surface 52c is located on the outer side of the U shape. The outer side of the U shape is the exterior-angle side of the first corner portion CR1 and is also the exterior-angle side of the second corner portion CR2.

Even with this configuration, the MOS transistor 50G can apply the gate voltage from three directions of the main surface 52a, the first side surface 52b, and the second side surface 52c of the semiconductor region 52 to pass drain current. Consequently, like the MOS transistor 50 of the first embodiment, the MOS transistor 50G can improve gate controllability and can prevent subthreshold characteristic degradation.

### Seventh Embodiment

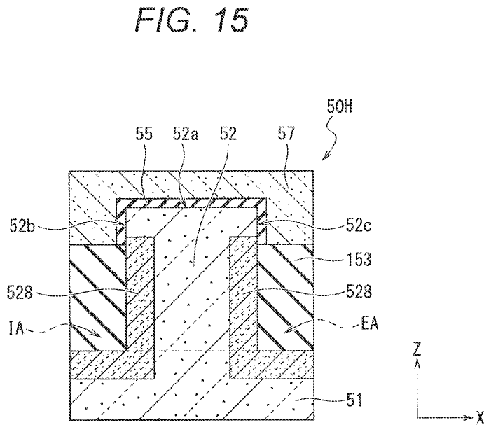

FIG. 15 is a cross-sectional view illustrating a configuration example of a MOS transistor 50H according to a seventh embodiment of the present disclosure. As illustrated in FIG. 15, the MOS transistor 50 H includes a P-type second impurity diffusion layer 528 provided on the first side surface 52b side and on the second side surface 52c side in the semiconductor region 52. The second impurity diffusion layer 528 is in contact with an element isolation film 153 of an STI structure. The element isolation film 153 may be constituted by a single-layer insulating film such as an SiO₂ film, or may be constituted by a laminated film in which an SiO₂ film and a silicon nitride film (SiN film) are stacked in two or more layers as will be described in a manufacturing method described later. The second impurity diffusion layer 528 has a higher P-type impurity concentration (acceptor concentration) than a region in contact with a gate insulating film 55 in the semiconductor region 52.

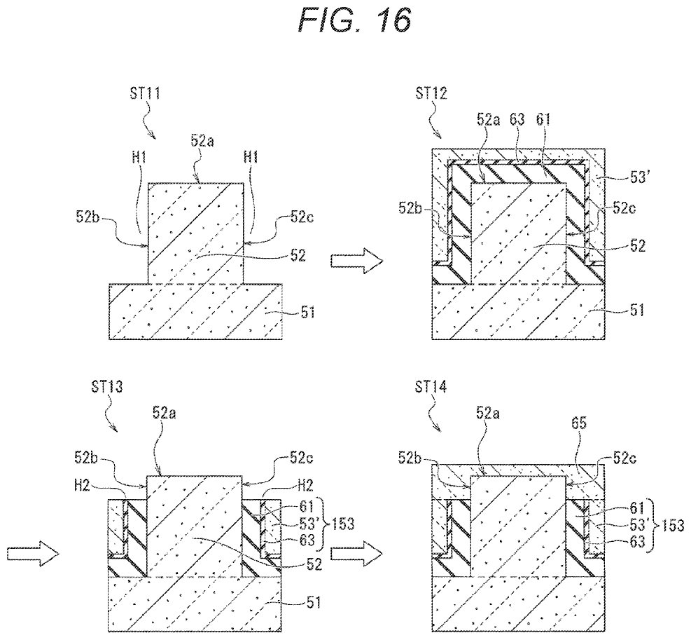

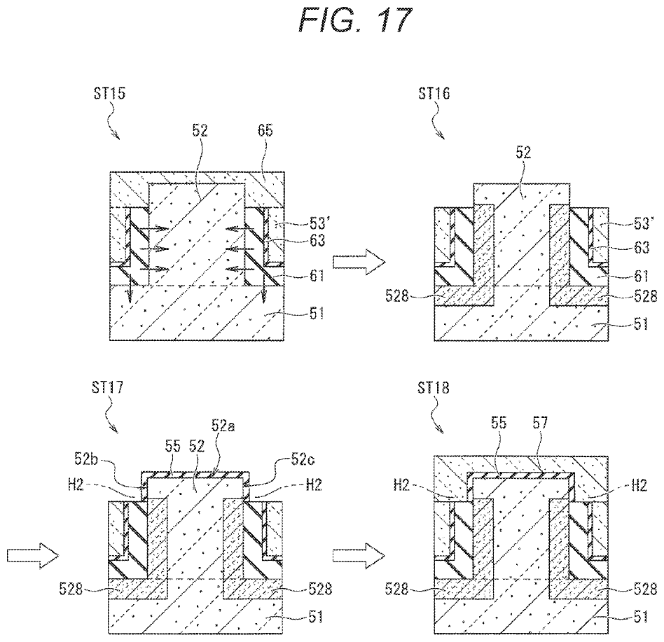

Next, an example of a method of manufacturing the MOS transistor 50H according to the seventh embodiment of the present disclosure will be described. FIGS. 16 and 17 are cross-sectional views illustrating the method of manufacturing the MOS transistor 50H according to the seventh embodiment of the present disclosure in order of processes. FIG. 16 illustrates steps ST11 to ST14, and FIG. 17 illustrates steps ST15 to ST18. Manufacturing equipment partially etches the front side of a semiconductor substrate 51 to form trenches H1 (step ST11). Step ST11 is the same process as step ST1 illustrated in FIG. 6. The semiconductor region 52 having a main surface 52a, the first side surface 52b, and the second side surface 52c is defined by forming the trenches H1.

Next, the manufacturing equipment sequentially deposits an SiO₂ film 61, a silicon nitride film (SiN film) 63, and an insulating film 53′ on the semiconductor substrate 51, using a CVD method (step ST12). The insulating film 53′ is, for example, an SiO₂ film. The SiO₂ film 61 contains a P-type impurity (acceptor) such as boron (B) at a high concentration. For example, the SiO₂ film 61 contains the P-type impurity at a higher concentration than the insulating film 53′.

Next, the manufacturing equipment sequentially etches the insulating film 53′, the SiN film 63, and the SiO₂ film 61 to form trenches H2 with these stacked films as the bottom surfaces (step ST13). This process may be referred to as recessing. The recessing may be performed by dry etching, wet etching, or a combination thereof. By the recessing, the main surface 52a, an upper portion of the first side surface 52b, and an upper portion of the second side surface 52c of the semiconductor region 52 are each exposed from the stacked films, and an element isolation film 153 includes these stacked films. In this example, the element isolation film 153 includes the stacked films including the insulating film 53′, the SiN film 63, and the SiO₂ film 61.

Next, the manufacturing equipment deposits an insulating film 65 on the semiconductor substrate 51 using a CVD method to cover the main surface 52a of the semiconductor region 52 (step ST14). The insulating film 65 is, for example, an SiO₂ film. Next, the manufacturing equipment applies annealing treatment to the entire substrate on which the insulating film 65 is formed. As a result, as indicated by arrows in step ST15, the P-type impurity is thermally diffused from the SiO₂ film 61 containing the P-type impurity such as boron (B) at the high concentration into the semiconductor substrate 51 and the semiconductor region 52 in contact with the SiO₂ film 61, forming the second impurity diffusion layer 528 in the semiconductor substrate 51 and the semiconductor region 52 (step ST16). In this process, since the SiN film 63 is present between the SiO₂ film 61 and the insulating film 53′, the P-type impurity is prevented from being thermally diffused from the SiO₂ film 61 into the insulating film 53′.

Next, the manufacturing equipment etches and removes the insulating film 65. This process may be referred to as recessing. The recessing may be performed by dry etching, wet etching, or a combination thereof. By the recessing, the main surface 52a, an upper portion of the first side surface 52b, and an upper portion of the second side surface 52c of the semiconductor region 52 are exposed.

The subsequent processes are similar to those in the method of manufacturing the MOS transistor 50 described with reference to FIG. 6. The manufacturing equipment thermally oxidizes the semiconductor region 52. As a result, the gate insulating film 55 is continuously formed on the main surface 52a, the upper portion of the first side surface 52b, and the upper portion of the second side surface 52c of the semiconductor region 52 (step ST17).

Next, the manufacturing equipment forms an electrode material (e.g., a polysilicon film) above the semiconductor substrate 51, using a CVD method, and fills the trenches H2. Next, the manufacturing equipment patterns the electrode material using photolithography and etching techniques. Thus, the manufacturing equipment forms a gate electrode 57 from the electrode material (step ST18). Then, the manufacturing equipment forms N-type drain and source regions. Through the above processes, the MOS transistor 50H is completed.

The MOS transistor 50H according to the seventh embodiment can apply the gate voltage from three directions of the main surface 52a, the first side surface 52b, and the second side surface 52c of the semiconductor region 52 to pass drain current. Consequently, like the MOS transistor 50 of the first embodiment, the MOS transistor 50H can improve gate controllability and can prevent subthreshold characteristic degradation.

Furthermore, in the MOS transistor 50H, a lower portion of the first side surface 52b and a lower portion of the second side surface 52c of the semiconductor region 52 are each in contact with the element isolation film 153. The concentration of the P-type impurity at a contact interface between the first side surface 52b and the element isolation film 153 is higher than the concentration of the P-type impurity at a contact interface between the first side surface 52b and the gate insulating film 55. The concentration of the P impurity at a contact interface between the second side surface 52c and the element isolation film 153 is higher than the concentration of the P impurity at a contact interface between the second side surface 52c and the gate insulating film 55.

At a contact interface between the second impurity diffusion layer 528 and the element isolation film 153, noise can be generated by charge. However, in the MOS transistor 50H, the P-type second impurity diffusion layer 528 is formed at portions in contact with the element isolation film 153 in the semiconductor region 52, and the concentration of the P-type impurity is high at the contact interfaces between the second impurity diffusion layer 528 and the element isolation film 153. At the contact interfaces, the P-type impurity (acceptor) traps charge, and thus the MOS transistor 50H can prevent noise generation. Note that the second impurity diffusion layer 528 may be referred to as acceptor doped regions.

### Other Embodiments

As described above, the present disclosure has been described with the embodiments and the modifications. However, the description and the drawings constituting part of this disclosure should not be understood to limit the present disclosure. From this disclosure, various alternative embodiments, examples, and operation techniques will be apparent to those skilled in the art. For example, two or more of the individual configurations of the second to seventh embodiments may be combined as desired as a configuration of an embodiment of the present disclosure. Furthermore, the above embodiments have described that the amplification transistor 34 is constituted by any one of the MOS transistors 50 and 50A to 50H, but other pixel transistors (the select transistor and the reset transistor) than the amplification transistor 34 may be constituted by any one of the MOS transistors 50 and 50A to 50H. Thus, it is a matter of course that the present technology includes various embodiments etc. not described herein. At least one of various omissions, substitutions, or changes of the components can be made without departing from the gist of the above-described embodiments and modifications. Furthermore, the effects described in the present description are merely examples and nonlimiting, and other effects may be included.

Note that the present disclosure can also have the following configurations.

(1)

A semiconductor device including:

a semiconductor substrate; and

a transistor provided on the semiconductor substrate,

the transistor including

a semiconductor region having a main surface and a first side surface intersecting the main surface,

a gate insulating film provided on the semiconductor region,

a gate electrode provided on the gate insulating film,

a channel region covered with the gate insulating film and the gate electrode in the semiconductor region, and

first-conductivity-type source and drain regions adjacent to the channel region,

in which in a planar view from the normal direction of the main surface,

the semiconductor region includes

a first portion extended in a first direction, and

a second portion extended from the first portion in a second direction intersecting the first direction, and

the channel region includes

a first channel region present on the main surface, and

a second channel region present on the first side surface and extending in the direction of depth of the semiconductor region.

(2)

The semiconductor device according to (1) above, in which the semiconductor region further includes

a second side surface located opposite the first side surface across the main surface,

the channel region further includes

a third channel region present on the second side surface and extending in the direction of depth of the semiconductor region,

the first side surface is located on the interior-angle side of a first corner portion formed by the first portion and the second portion, and

the second side surface is located on the exterior-angle side of the first corner portion.

(3)

The semiconductor device according to (2) above, in which the gate insulating film includes

a first film portion covering the main surface,

a second film portion covering the first side surface, and

a third film portion covering the second side surface, and

the second film portion has a greater film thickness than the third film portion.

(4)

The semiconductor device according to (2) above, in which the gate insulating film includes

a first film portion covering the main surface,

a second film portion covering the first side surface, and

a third film portion covering the second side surface, and

the third film portion has a longer length in the depth direction from the main surface than the second film portion.

(5)

The semiconductor device according to (3) or (4) above, in which

the transistor further includes

a second-conductivity-type impurity diffusion layer provided on the side of the first side surface in the semiconductor region, and

the impurity diffusion layer has a higher impurity concentration than a region located on the side of the second side surface in the semiconductor region.

(6)

The semiconductor device according to any one of (3) to (5) above, further including an element isolation film provided on the semiconductor substrate and being in contact with each of the first side surface and the second side surface,

in which the concentration of a second-conductivity-type impurity at a contact interface between the first side surface and the element isolation film is higher than the concentration of the second-conductivity-type impurity at a contact interface between the first side surface and the gate insulating film, and

the concentration of the second-conductivity-type impurity at a contact interface between the second side surface and the element isolation film is higher than the concentration of the second-conductivity-type impurity at a contact interface between the second side surface and the gate insulating film.

(7)

The semiconductor device according to any one of (2 to 6 above, in which

in a planar view from the normal direction of the main surface,

the semiconductor region further includes

a third portion extended from the first portion in the second direction and facing the second portion in the first direction,

the first side surface is located on the interior-angle side of a second corner portion formed by the first portion and the third portion, and

the second side surface is located on the exterior-angle side of the second corner portion.

(8)

The semiconductor device according to any one of (1) to (7) above, in which

the semiconductor region includes a trench provided on the main surface and extended in channel length directions.

(9)

An imaging apparatus including:

a pixel that performs photoelectric conversion; and

an amplification transistor that amplifies a voltage signal corresponding to the level of charge output from the pixel,

the amplification transistor including

a semiconductor region having a main surface and a first side surface intersecting the main surface,

a gate insulating film provided on the semiconductor region,

a gate electrode provided on the gate insulating film,

a channel region covered with the gate insulating film and the gate electrode in the semiconductor region, and

first-conductivity-type source and drain regions adjacent to the channel region,

in which in a planar view from the normal direction of the main surface,

the semiconductor region includes

a first portion extended in a first direction, and

a second portion extended from the first portion in a second direction intersecting the first direction, and

the channel region includes

a first channel region present on the main surface, and

a second channel region present on the first side surface and extending in the direction of depth of the semiconductor region.

(10)

An imaging apparatus including:

a pixel that performs photoelectric conversion; and

a readout circuit that reads out a signal photoelectrically converted in the pixel,

in which the pixel includes

a floating diffusion that temporarily stores charge generated by photoelectric conversion,

the readout circuit includes

an amplification transistor that amplifies a voltage signal corresponding to the level of charge output from the floating diffusion,

a select transistor that controls timing to output the signal amplified by the amplification transistor from the readout circuit, and

a reset transistor that resets the potential of the floating diffusion to a preset potential,

at least one transistor of the amplification transistor, the select transistor, or the reset transistor includes

a semiconductor region having a main surface and a first side surface intersecting the main surface,

a gate insulating film provided on the semiconductor region,

a gate electrode provided on the gate insulating film,

a channel region covered with the gate insulating film and the gate electrode in the semiconductor region, and

first-conductivity-type source and drain regions adjacent to the channel region,

in a planar view from the normal direction of the main surface,

the semiconductor region includes

a first portion extended in a first direction, and

a second portion extended from the first portion in a second direction intersecting the first direction, and

the channel region includes

a first channel region present on the main surface, and

a second channel region present on the first side surface and extending in the direction of depth of the semiconductor region.

### REFERENCE SIGNS LIST

1 Imaging apparatus
12 Pixel
13 Vertical drive circuit
14 Column signal processing circuit
15 Horizontal drive circuit
16 Output circuit
17 Control circuit
21 A plurality of pixels
22 Horizontal signal line
23 Vertical signal line
24 Data output signal line
30 Readout circuit
31 Photodiode
32 Transfer transistor
33 Floating diffusion
34 Amplification transistor
35 Select transistor
36 Reset transistor
50, 50A to 50H MOS transistor
51 Semiconductor substrate
52 Semiconductor region
52a Main surface
52b First side surface
52c Second side surface
53 Element isolation film
53′ Insulating film
55 Gate insulating film
57 Gate electrode
58 Drain region
59 Source region
61 SiO₂ film
63 SiN film
65 Insulating film
153 Element isolation film
521 First portion
522 Second portion
523 Third portion
525 First impurity diffusion layer
526, 527 Portion
528 Second impurity diffusion layer
551 First film portion
552 Second film portion
553 Third film portion
554 Fourth film portion
555 Fifth film portion
CH Channel region
CH1 First channel region
CH2 Second channel region
CH3 Third channel region
CP1, CP2 Current path
CR1 First corner portion
CR2 Second corner portion
EA exterior angle
H1, H2, H3 Trench
IA interior angle
RST Reset signal
SEL Selection signal
TRG Transfer signal
Vdd Drain power supply

1. A semiconductor device comprising:
a semiconductor substrate; and
a transistor provided on the semiconductor substrate,
the transistor including
a semiconductor region having a main surface and a first side surface intersecting the main surface,
a gate insulating film provided on the semiconductor region,
a gate electrode provided on the gate insulating film,
a channel region covered with the gate insulating film and the gate electrode in the semiconductor region, and
first-conductivity-type source and drain regions adjacent to the channel region,
wherein in a planar view from a normal direction of the main surface,
the semiconductor region includes
a first portion extended in a first direction, and
a second portion extended from the first portion in a second direction intersecting the first direction, and
the channel region includes
a first channel region present on the main surface, and
a second channel region present on the first side surface and extending in a direction of depth of the semiconductor region.

2. The semiconductor device according to claim 1, wherein
the semiconductor region further includes
a second side surface located opposite the first side surface across the main surface,
the channel region further includes
a third channel region present on the second side surface and extending in the direction of depth of the semiconductor region,
the first side surface is located on an interior-angle side of a first corner portion formed by the first portion and the second portion, and
the second side surface is located on an exterior-angle side of the first corner portion.

3. The semiconductor device according to claim 2, wherein
the gate insulating film includes
a first film portion covering the main surface,
a second film portion covering the first side surface, and
a third film portion covering the second side surface, and
the second film portion has a greater film thickness than the third film portion.

4. The semiconductor device according to claim 2, wherein
the gate insulating film includes
a first film portion covering the main surface,
a second film portion covering the first side surface, and
a third film portion covering the second side surface, and
the third film portion has a longer length in the depth direction from the main surface than the second film portion.

5. The semiconductor device according to claim 3, wherein
the transistor further includes
a second-conductivity-type impurity diffusion layer provided on a side of the first side surface in the semiconductor region, and
the impurity diffusion layer has a higher impurity concentration than a region located on a side of the second side surface in the semiconductor region.

6. The semiconductor device according to claim 3, further comprising an element isolation film provided on the semiconductor substrate and being in contact with each of the first side surface and the second side surface,
wherein a concentration of a second-conductivity-type impurity at a contact interface between the first side surface and the element isolation film is higher than a concentration of the second-conductivity-type impurity at a contact interface between the first side surface and the gate insulating film, and
a concentration of the second-conductivity-type impurity at a contact interface between the second side surface and the element isolation film is higher than a concentration of the second-conductivity-type impurity at a contact interface between the second side surface and the gate insulating film.

7. The semiconductor device according to claim 2, wherein
in a planar view from the normal direction of the main surface,
the semiconductor region further includes
a third portion extended from the first portion in the second direction and facing the second portion in the first direction,
the first side surface is located on an interior-angle side of a second corner portion formed by the first portion and the third portion, and
the second side surface is located on an exterior-angle side of the second corner portion.

8. The semiconductor device according to claim 1, wherein
the semiconductor region includes a trench provided on the main surface and extended in channel length directions.

9. An imaging apparatus comprising:
a pixel that performs photoelectric conversion; and
an amplification transistor that amplifies a voltage signal corresponding to a level of charge output from the pixel,
the amplification transistor including
a semiconductor region having a main surface and a first side surface intersecting the main surface,
a gate insulating film provided on the semiconductor region,
a gate electrode provided on the gate insulating film,
a channel region covered with the gate insulating film and the gate electrode in the semiconductor region, and
first-conductivity-type source and drain regions adjacent to the channel region,
wherein in a planar view from a normal direction of the main surface,
the semiconductor region includes
a first portion extended in a first direction, and
a second portion extended from the first portion in a second direction intersecting the first direction, and
the channel region includes
a first channel region present on the main surface, and
a second channel region present on the first side surface and extending in a direction of depth of the semiconductor region.

10. An imaging apparatus comprising:
a pixel that performs photoelectric conversion; and
a readout circuit that reads out charge generated by photoelectric conversion in the pixel,
wherein the pixel includes
a floating diffusion that temporarily stores charge generated by photoelectric conversion,
the readout circuit includes
an amplification transistor that amplifies a voltage signal according to a level of charge output from the floating diffusion,
a select transistor that controls timing to output the signal amplified by the amplification transistor from the readout circuit, and
a reset transistor that resets a potential of the floating diffusion to a preset potential,
at least one transistor of the amplification transistor, the select transistor, or the reset transistor includes
a semiconductor region having a main surface and a first side surface intersecting the main surface,
a gate insulating film provided on the semiconductor region,
a gate electrode provided on the gate insulating film,
a channel region covered with the gate insulating film and the gate electrode in the semiconductor region, and
first-conductivity-type source and drain regions adjacent to the channel region,
in a planar view from a normal direction of the main surface,
the semiconductor region includes
a first portion extended in a first direction, and
a second portion extended from the first portion in a second direction intersecting the first direction, and
the channel region includes
a first channel region present on the main surface, and
a second channel region present on the first side surface and extending in a direction of depth of the semiconductor region.
